(19) United States
(12) Patent Application Publication
(10) Pub. No.: US 2026/0343959 A1
(43) Pub. Date: Oct. 29, 2026

(54) TRENCH JUNCTION FIELD-EFFECT TRANSISTOR WITH SEPARATED SOURCE AND GATE REGIONS

(71) Applicant: Microchip Technology Incorporated, Chandler, AZ (US)

(72) Inventor: Shesh Pandey, Gilbert, AZ (US)

(73) Assignee: Microchip Technology Incorporated, Chandler, AZ (US)

(21) Appl. No.: 19/247,578

(22) Filed: Jun. 24, 2025

Related U.S. Application Data
(60) Provisional application No. 63/796,958, filed on Apr. 29, 2025.

(51) Int. Cl. H10D 30/83; H10D 30/01; H10D 62/17; H10D 62/83; H10D 62/832; H10D 84/87

(52) U.S. Cl. CPC H10D 30/831; H10D 30/0515; H10D 62/328; H10D 62/343; H10D 84/87; H10D 62/83; H10D 62/8325

(57) ABSTRACT

Junction field-effect transistors (JFETs) with separated source and gate regions, and methods of forming the same, are disclosed herein. In one example, a semiconductor device includes a source region, a drain region, a drift region, and multiple gate regions. The source region is within a mesa and has a first conductivity type. The drain region is below the source region and also has the first conductivity type. The drift region extends vertically between the source region and the drain region, and the drift region also has the first conductivity type, but the drift region has a lower doping concentration than the source region and the drain region. The gate regions are below trenches on opposite sides of the mesa, separated from the source region, and the gate regions have a second conductivity type different than the first conductivity type.

### CROSS-REFERENCE TO RELATED APPLICATIONS

This patent application claims the benefit of the filing date of U.S. Provisional Patent Application No. 63/796,958, filed Apr. 29, 2025, and entitled “TRENCH JUNCTION FIELD-EFFECT TRANSISTOR WITH GATE REGIONS EXTENDING BELOW TRENCH FLOOR,” the contents of which are hereby expressly incorporated by reference.

### TECHNICAL FIELD

The present disclosure relates generally to semiconductor devices with p-n junctions, and more particularly, though not exclusively, to junction field-effect transistors (JFETs).

### BACKGROUND

Silicon carbide (SiC) JFETs are well-suited for power electronic applications due to their ultra-low on-resistance, high thermal stability, and ability to sustain high-voltage operation. However, conventional SiC JFETs suffer from various drawbacks, including stringent process control requirements and high capacitance, which may lead to lower performance.

### SUMMARY OF THE INVENTION

This disclosure presents examples of trench JFETs with separated source and gate regions, along with devices and systems incorporating the same, and methods of forming the same. In the described examples, the gate regions are separated from the source region, which may enhance process control and reduce capacitance, thus improving performance.

In one example, a semiconductor device includes a source region, a drain region, a drift region, and multiple gate regions. The source region is within a mesa and has a first conductivity type. The drain region is below the source region and also has the first conductivity type. The drift region extends vertically between the source region and the drain region, and the drift region also has the first conductivity type, but the drift region has a lower doping concentration than the source region and the drain region. The gate regions are below trenches on opposite sides of the mesa, separated from the source region, and the gate regions have a second conductivity type different than the first conductivity type.

In another example, a power circuit includes one or more JFETs having a source region, a drain region, a drift region, and multiple gate regions. The source region is within a mesa. The drain region is below the source region. The drift region is between the source region and the drain region. The gate regions are below trenches on opposite sides of the mesa, and the gate regions do not extend to the source region.

In another example, a method includes: (i) receiving a substrate including a first doped semiconductor material having a first conductivity type; (ii) forming a drift layer over the substrate, where the drift layer includes a second doped semiconductor material having the first conductivity type; (iii) implanting a first type of dopant ions in a source region of the drift layer, where the first type of dopant ions correspond to the first conductivity type; (iv) implanting a second type of dopant ions in lower gate regions of the drift layer, where the second type of dopant ions correspond to a second conductivity type different than the first conductivity type; (v) implanting the second type of dopant ions in upper gate regions of the drift layer; and (vi) forming trenches in the upper gate regions.

### BRIEF DESCRIPTION OF THE DRAWINGS

FIGS. 1A-B illustrate an example of a trench JFET with separated source and gate regions.

FIGS. 2A-C illustrate examples of modulating the channel conductivity of a trench JFET.

FIGS. 3A-G illustrate an example process flow for forming a trench JFET with separated source and gate regions.

FIG. 4 illustrates a flowchart for a method of forming a trench JFET with separated source and gate regions.

FIG. 5 illustrates an example integrated circuit device that may include one or more JFETs in accordance with examples disclosed herein.

FIG. 6 illustrates an example computing system that may include one or more JFETs in accordance with examples disclosed herein.

### DETAILED DESCRIPTION

A junction field-effect transistor (JFET) is a type of field-effect transistor (FET) that uses a reverse-biased p-n junction to control current flow through a semiconductor channel. JFETs are voltage-controlled devices, meaning the input (gate) voltage regulates the output (drain-source) current.

Silicon carbide (SiC) JFETs are a type of JFET implemented using SiC as the semiconductor. SiC JFETs are advantageous due to their ultra-low on-resistance, high thermal stability, and ability to sustain high-voltage operation. These advantages stem from the intrinsic properties of SiC, including its wide bandgap, high critical electric field strength, and high thermal conductivity. As a result, SiC JFETs are particularly well-suited for power electronics applications, such as circuit protection, solid-state circuit breakers, and high-power switching.

In some cases, SiC JFETs may be implemented as trench JFETs, which are JFETs with trenches etched on each side of the source region to define the gate regions. In these designs, the trench etch is a critical operation with low process tolerance, as misaligned trenches can impact the critical dimensions of the gate regions (e.g., producing gate regions that are that are too wide or too narrow), which leads to variations in gate resistance. In addition, trench JFETs may suffer from high capacitance due to the close proximity between the source and gate regions, as the gate regions extend upward along the floor and sidewall of the trenches and eventually make contact with the source region.

Accordingly, this disclosure presents examples of a trench JFET structure with separated source and gate regions, along with methods of forming the same.

In some examples, a JFET may include a source region, a drain region, a drift region extending vertically between the source and drain regions, and trenches adjacent to the source region that extend into the drift region. In addition, the JFET may include gate regions that extend downward below the floor of the trenches, into the drift region, and then towards each other, thus defining a channel region in a narrow area of the drift region between the gate regions and below the mesa where the source region resides.

In this manner, the gate and channel regions are vertically offset from the source region and positioned at a lower level of the drift region, completely outside the mesa, thus providing separation between the source and gate regions and eliminating direct physical contact between them. As a result, the separation between the source and gate regions reduces gate-source capacitance. Further, the position and design of the gate regions relaxes the trench etch and alignment requirements during fabrication, as the critical dimensions of the gate regions are not impacted by trench misalignment.

The described JFET examples may provide various advantages, including lower gate-source capacitance due to the separation between the source and gate regions, and easier process control since the trench etch is no longer critical due to the position and design of the gate regions. Further, no extra mask is required for any process operations. These examples enable enhanced switching performance, improved manufacturability, and greater reliability for high-performance and robust JFET devices with ultra-low on-resistance, high-temperature stability, and high-voltage operation.

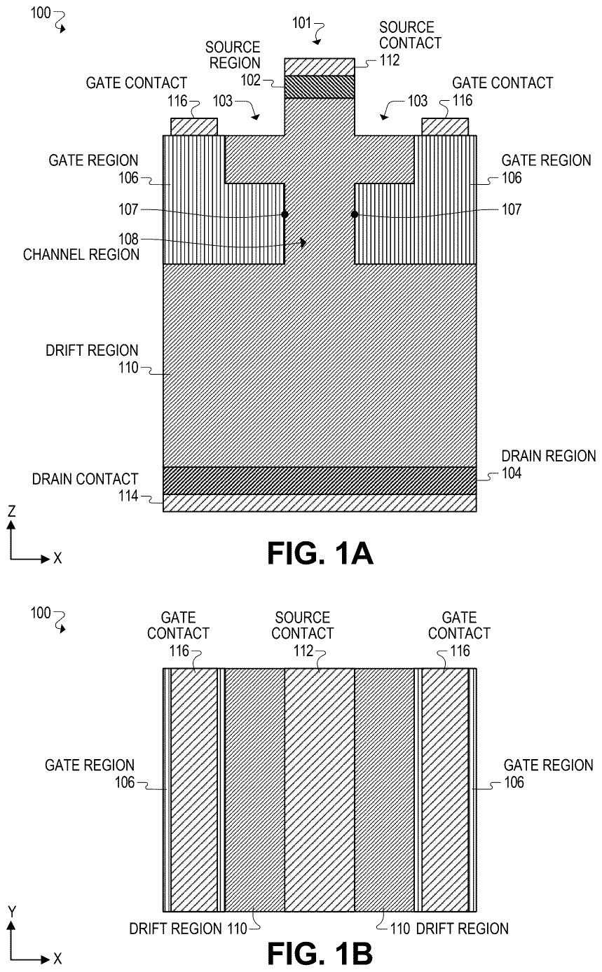

FIGS. 1A-B illustrate an example of a trench JFET 100 with separated source and gate regions 102, 106. In particular, FIG. 1A shows a cross-section (x-z plane) view of trench JFET 100, and FIG. 1B shows a plan (x-y plane) view of trench JFET 100.

In the illustrated example, trench JFET 100 includes a source region 102 positioned within a mesa 101 between two trenches 103, a drain region 104 below the source region 102, a drift region 110 extending vertically between the source and drain regions 102, 104, and gate regions 106 below the trenches 103. JFET 100 also includes conductive (e.g., metal) source, drain, and gate contacts 112, 114, and 116 on the source, drain, and gate regions 102, 104, 106, respectively.

The gate regions 106 extend downward from the floor of the trenches 103 and into the drift region 110 (e.g., away from the source region 102), and then towards each other within the bulk of the drift region 110. As a result, a channel region 108 is defined in a narrow area of the drift region 110 between the ends of the respective gate regions 106 and below the mesa 101 where the source region 102 resides.

In this manner, the gate and channel regions 106, 108 are vertically offset from the source region 102 and positioned at a lower level of the drift region 110, completely outside the mesa 101, thus providing vertical separation between the source and gate regions 102, 106. The separation between the source and gate regions 102, 106 reduces gate-source capacitance, which enhances the performance of JFET 100. Moreover, the position and design of the gate regions 106 relaxes the trench etch and alignment requirements during fabrication, as the critical dimensions of the gate regions 106 are not impacted by trench misalignment.

The source, drain, gate, channel, and drift regions 102, 104, 106, 108, 110 are made of semiconductor materials, such as silicon carbide (SiC) or silicon (Si). Moreover, the source, drain, channel, and drift regions 102, 104, 108, 110 all have the same type of conductivity (e.g., n-type or p-type conductivity), while the gate regions 106 have the opposite type of conductivity.

For example, the source, drain, channel, and drift regions 102, 104, 108, 110 may include semiconductor materials that are all doped with n-type dopants or p-type dopants, while the gate regions 106 may include semiconductor materials that are doped with the opposite type of dopants. Moreover, in some examples, the source, drain, and gate regions 102, 104, 106 may be heavily doped, while the drift and channel regions 110, 108 may be lightly doped.

For example, for an n-type JFET 100, the source and drain regions 102 may include heavily-doped n-type (n+) semiconductors, the drift and channel regions 110, 108 may include lightly-doped n-type (n−) semiconductors, and the gate regions 106 may include heavily-doped p-type (p+) semiconductors.

Alternatively, for a p-type JFET 100, the source and drain regions 102 may include heavily-doped p-type (p+) semiconductors, the drift and channel regions 110, 108 may include lightly-doped p-type (p−) semiconductors, and the gate regions 106 may include heavily-doped n-type (n+) semiconductors.

As a result, multiple p-n junctions 107 are formed between the respective gate regions 106 and the channel region 108. In this manner, the conductivity of the channel region 108 can be controlled based on the gate voltage (e.g., the voltage applied to the gate regions 106 via the gate contacts 116).

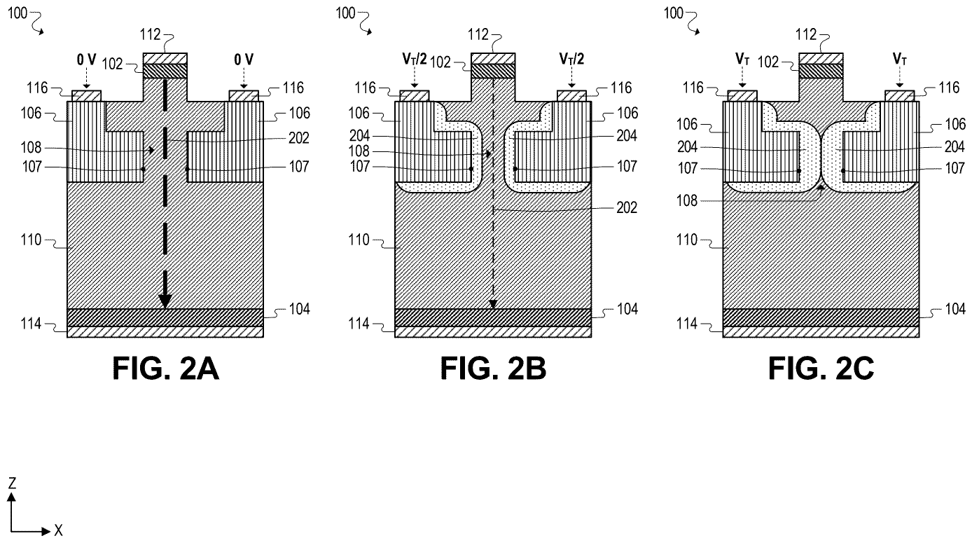

As an example, FIGS. 2A-C illustrate the operation of JFET 100 when various gate voltages are applied. In particular, JFET 100 is a normally-on device with a reverse-biased gate 106, which means current 202 flows unrestricted from source region 102 to drain region 104 (e.g., through the channel region 108) when no gate voltage is applied. This is shown in FIG. 2A, where no gate voltage (0 V) is applied, and current 202 flows unrestricted from source region 102 to drain region 104.

When a gate voltage below a threshold (V_{T}) is applied (e.g., negative voltage for an n-type JFET 100, positive voltage for a p-type JFET 100), depletion regions 204 form at the respective p-n junctions 107, which reduces the width of the channel 108 and restricts the flow of current 202 through the channel 108. This is shown in FIG. 2B, where half the threshold gate voltage (V_{T}/2) is applied, which forms depletion regions 204 that cut the channel 108 width in half, thus reducing current flow 202.

As the magnitude of the gate voltage increases, the depletion regions 204 widen and the channel 108 narrows, further restricting the flow of current 202. Once a threshold gate voltage is reached, the depletion regions 204 merge and the channel 108 becomes completely “pinched off” or closed, preventing current 202 from flowing through the channel 108 altogether (e.g., from source region 102 to drain region 104). This is shown in FIG. 2C, where the threshold gate voltage (V_{T}) is applied, which causes the depletion regions 204 to merge and prevents current 202 from flowing through the channel 108.

In some examples, JFET 100 may be implemented in power delivery or power management circuitry. In particular, JFET 100 is well-suited for power electronics applications, such as circuit protection, solid-state circuit breakers, and high-power switching. Thus, in some cases, JFET 100 may be included in a power circuit, such as a protection circuit (e.g., for overvoltage, overcurrent, or electrostatic discharge (ESD) protection), a solid-state circuit breaker, or a power switching circuit.

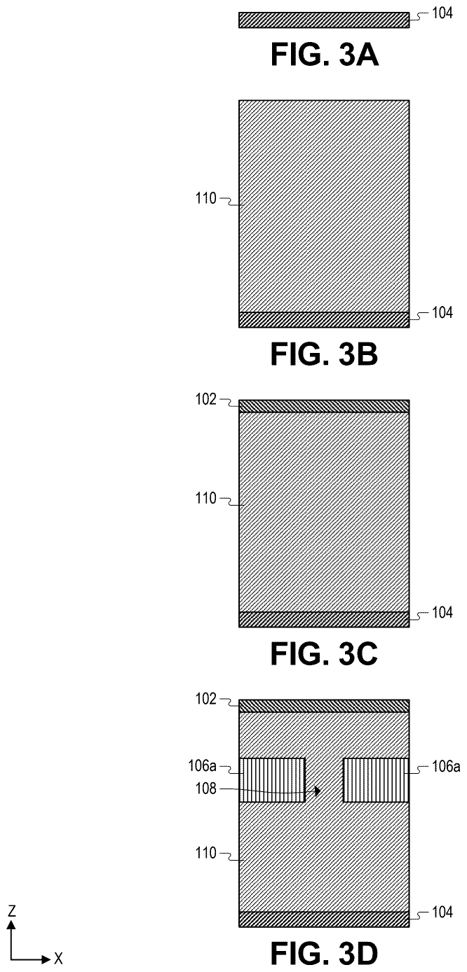

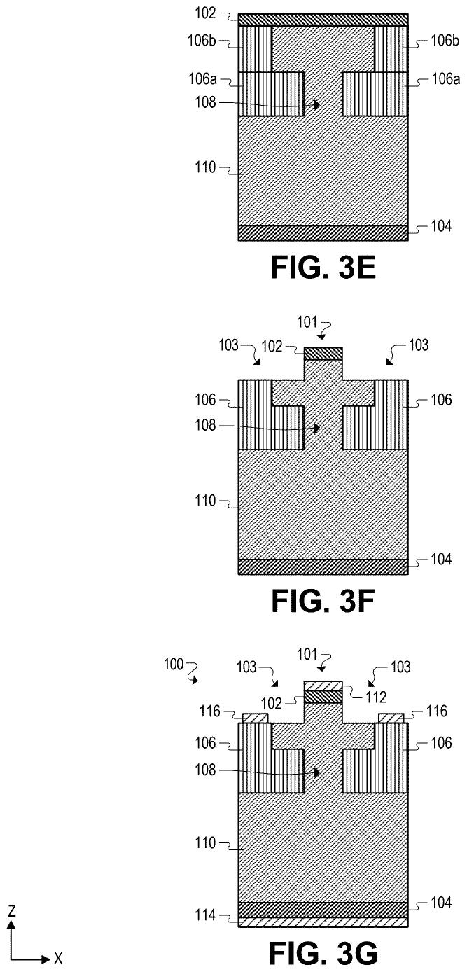

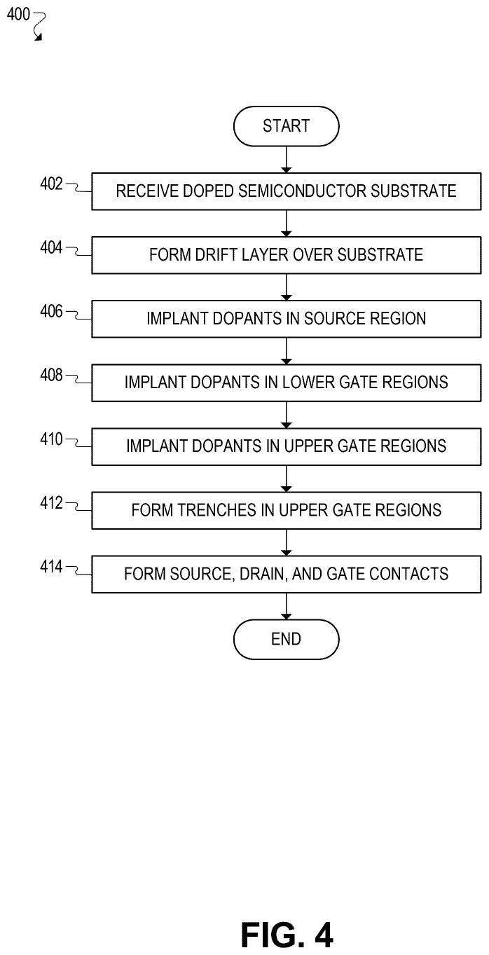

FIGS. 3A-G illustrate an example process flow for forming a trench JFET 100 with separated source and gate regions 102, 106, and FIG. 4 illustrates a flowchart 400 for a method of performing the process flow shown in FIGS. 3A-G. In the illustrated example, FIGS. 3A-G show cross-section (x-z plane) views after various operations of the process flow are performed, and flowchart 400 shows the flow of operations in the corresponding method. It will be appreciated in light of the present disclosure that the illustrated process flow is one example methodology for arriving at trench JFET 100.

Turning to flowchart 400, the method begins at block 402 by receiving a doped semiconductor substrate 104, as shown in FIG. 3A. The doped semiconductor substrate 104 serves as the drain region. The doped semiconductor substrate 104 may include a doped semiconductor material having a first conductivity type (e.g., n-type or p-type conductivity). In some examples, the doped semiconductor substrate 104 may be a doped silicon carbide (SiC) substrate. Moreover, the doped semiconductor substrate 104 may be heavily doped with n-type (n+) or p-type (p+) dopants. For example, for an n-type JFET, the doped semiconductor substrate 104 may be an n+ SiC substrate (e.g., SiC substrate doped heavily with n-type dopants). Alternatively, for a p-type JFET, the doped semiconductor substrate 104 may be a p+ SiC substrate (e.g., SiC substrate doped heavily with p-type dopants).

In other examples, the doped semiconductor substrate 104 may be a doped silicon (Si) substrate instead of a doped silicon carbide (SiC) substrate.

The method then proceeds to block 404 to form a doped semiconductor layer 110 over the substrate 104, as shown in FIG. 3B. The doped semiconductor layer 110 serves as the drift region, which may also be referred to herein as the drift layer. The drift layer 110 may include a doped semiconductor material having the same conductivity type (e.g., n-type or p-type conductivity) as the semiconductor substrate 104 (e.g., the drain region). In some examples, the drift layer 110 may include the same semiconductor material and same type of dopants as the semiconductor substrate 104, but the drift layer 110 may be lightly doped instead of heavily doped. For example, if the doped semiconductor substrate 104 is an n+ SiC substrate, the drift layer 110 may be an n− SiC layer (e.g., SiC layer doped lightly with n-type dopants). Alternatively, if the doped semiconductor substrate 104 is a p+ SiC substrate, the drift layer 110 may be a p− SiC layer (e.g., SiC layer doped lightly with p-type dopants).

The method then proceeds to block 406 to implant dopants in the source region 102 of the drift layer 110, as shown in FIG. 3C. In some examples, the dopants may be implanted using ion implantation. For example, a particular type and concentration of dopant ions may be implanted at a target depth/position in the drift layer 110, which corresponds to the location of the source region 102. In the illustrated example, the dopant ions are implanted at or near the upper surface of the drift layer 110, thus forming the source region 102 at the top of the drift layer 110 (e.g., on the surface). The particular type of dopant ions (e.g., p-type or n-type dopants) corresponds to the conductivity type (e.g., p-type or n-type conductivity) of the semiconductor substrate 104 (e.g., drain region) and the drift layer 110.

In some examples, the source region 102 may be implanted with the same type of dopants as the drift layer 110, but the source region 102 may be heavily doped instead of lightly doped. For example, if the drift layer 110 is lightly doped with n-type dopants, the source region 102 may be heavily doped with n-type dopants. In this manner, the source region 102 may be a heavily-doped region containing the same semiconductor material and same type of dopants as the drift layer 110.

For example, if the drift layer 110 is an n− SiC layer, the source region 102 may be an n+ SiC region (e.g., SiC region doped heavily with n-type dopants). Alternatively, if the drift layer 110 is a p− SiC layer, the source region 102 may be a p+ SiC region (e.g., SiC region doped heavily with p-type dopants).

In this manner, the source region 102 has the same conductivity type (e.g., n-type or p-type conductivity) as the semiconductor substrate 104 (e.g., drain region) and the drift layer 110. Moreover, the source region 102 is heavily doped with the same or similar doping concentration as the semiconductor substrate 104 (e.g., drain region).

The method then proceeds to block 408 to implant dopants in the lower gate regions 106a of the drift layer 110, as shown in FIG. 3D. In some examples, the dopants may be implanted using ion implantation. For example, a particular type and concentration of dopant ions may be implanted in the drift layer 110 at a target depth/position (e.g., along the z/x axes), which corresponds to the location of the lower gate regions 106a. In the illustrated example, the dopant ions are implanted at a particular depth (e.g., along the z axis) in the bulk of the drift layer 110 (e.g., below the surface), and in multiple positions (e.g., along the x axis) at that depth, leaving an undoped area in the middle. In this manner, multiple lower gate regions 106a are formed on opposing sides of the drift layer 110 in the bulk. As a result, a channel region 108 is defined within the drift layer 110 in the area between the lower gate regions 106a.

The particular type of dopant ions (e.g., p-type or n-type dopants) corresponds to the opposite conductivity type (e.g., p-type or n-type conductivity) of the semiconductor substrate 104 (e.g., drain region), the drift layer 110, and the source region 102.

In some examples, the lower gate regions 106a may be implanted with the opposite type of dopants as the drift layer 110, and the lower gate regions 106a may be heavily doped instead of lightly doped. For example, if the drift layer 110 is lightly doped with n-type dopants, the lower gate regions 106a may be heavily doped with p-type dopants. In this manner, the lower gate regions 106a may include the same semiconductor material as the drift layer 110 but heavily doped with the opposite type of dopants.

For example, if the drift layer 110 is an n− SiC layer, the lower gate regions 106a may be p+ SiC regions (e.g., SiC regions doped heavily with p-type dopants). Alternatively, if the drift layer 110 is a p− SiC layer, the lower gate regions 106a may be n+ SiC regions (e.g., SiC regions doped heavily with n-type dopants).

The method then proceeds to block 410 to implant dopants in the upper gate regions 106b of the drift layer 110, as shown in FIG. 3E. In some examples, the dopants may be implanted using ion implantation. For example, a particular type and concentration of dopant ions may be implanted in the drift layer 110 at a target depth/position (e.g., along the z/x axes), which corresponds to the location of the upper gate regions 106b. In the illustrated example, the dopant ions are implanted in the drift layer 110 at a depth (e.g., along the z axis) extending between the lower gate regions 106a and the source region 102, and in multiple positions (e.g., along the x axis) at that depth, leaving an undoped area in the middle. Moreover, the areas in which the dopant ions are implanted are narrower than the lower gate regions 106a, thus leaving a wider undoped area in the middle compared to the lower gate regions 106a.

As a result, upper gate regions 106b are formed on top of the lower gate regions 106a on opposing sides of the drift layer 110. The lower gate regions 106a are below the upper gate regions 106b, are wider than the upper gate regions 106b, and extend further laterally into the drift layer 110 than the upper gate regions 106b. In this manner, the upper and lower gate regions 106a, b collectively form multiple gate regions 106 on opposing sides of the drift layer 110.

In some examples, the upper gate regions 106b may be implanted with the same type and concentration of dopants as the lower gate regions 106a. For example, if the lower gate regions 106a are heavily doped with p-type dopants, the upper gate regions 106b may also be heavily doped with p-type dopants. Alternatively, if the lower gate regions 106a are heavily doped with n-type dopants, the upper gate regions 106b may also be heavily doped with n-type dopants.

The method then proceeds to block 412 to form trenches 103 in the upper gate regions 106 (e.g., by etching away areas on the sides of the source region 102), as shown in FIG. 3F. As a result, the source region 102 resides within a mesa 101 formed between the trenches 103, and the gate regions 106 extend below the floor of the trenches 103 and towards each other. In this manner, the source region 102 is vertically separated from the gate regions 106 and the channel region 108.

The method then proceeds to block 414 to form conductive contacts 112, 114, 116 on the source, drain, and (upper) gate regions 102, 104, 106, as shown in FIG. 3G. In particular, a source contact 112 is formed above the source region 102, a drain contact 114 is formed below the drain region 104, and gate contacts 116 are formed above the gate regions 106.

The processing of trench JFET 100 may now be complete. In the illustrated example, the completed JFET 100 includes a source region 102 within a mesa 101 (e.g., between trenches 103), a drain region 104 below the source region 102 (e.g., at the bottom of JFET 100), a drift layer 110 extending vertically between the source and drain regions 102, 104, gate regions 106 extending downward from the floor of the respective trenches 103 and towards each other, a channel region 108 between opposing ends of the gate regions 106, and conductive contacts 112, 114, and 116 on the source, drain, and gate regions 102, 104, 106, respectively.

Any remaining processing may now be performed, such as dielectric filling, planarization, interconnect patterning, interconnect bump formation, singulation, and packaging/assembly. For example, in wafer-or panel-level process flows, the completed wafer or panel may be diced to singulate the IC dies on the wafer or panel. The respective IC dies may then be assembled in an IC package, attached to a circuit board, or incorporated into an electronic device or system.

At this point, the method may be complete. In some examples, however, the method may restart or certain blocks may be repeated. For example, in some examples, the method may restart at block 402 to continue forming trench JFETs with the same or similar design.

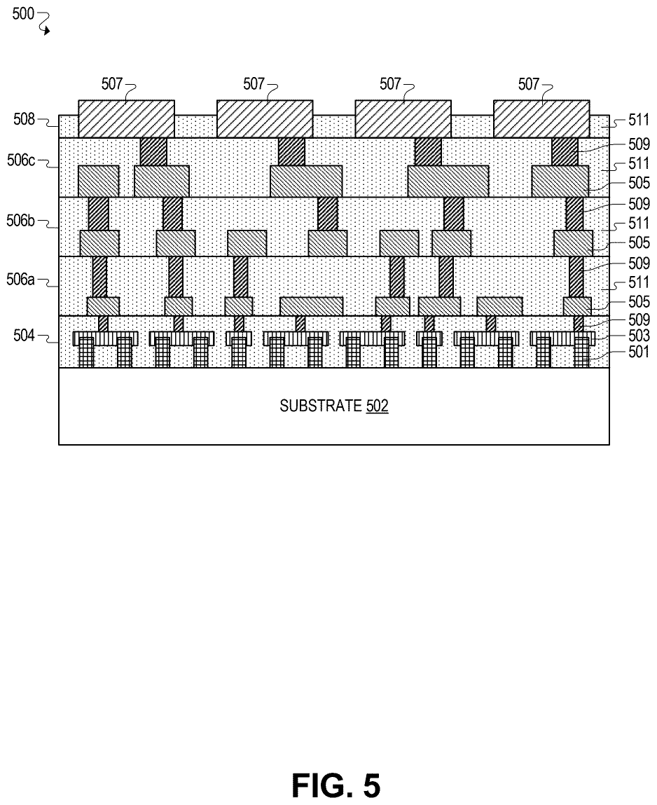

FIG. 5 illustrates an example integrated circuit (IC) device 500 that may include one or more JFETs in accordance with examples disclosed herein (e.g., JFET 100). In some examples, IC device 500 may be included in an IC die, such as a system-on-chip (SoC) die, processor die, memory die, input/output (I/O) die, or power die (e.g., power management integrated circuit (PMIC)), among other examples.

In the illustrated example, IC device 500 includes a semiconductor substrate 502, a device layer 504 over the semiconductor substrate 502, multiple internal interconnect layers 506a-c over the device layer 504, and an external interconnect layer 508 over the internal interconnect layers 506a-c (e.g., on the upper surface of IC device 500).

The semiconductor substrate 502 may include any suitable semiconductor material, including, without limitation, silicon, silicon carbide, silicon germanium, germanium, indium antimonide, lead telluride, indium arsenide, indium phosphide, gallium arsenide, gallium antimonide, or other group II-VI, III-V, or IV semiconductor materials.

The device layer 504 may include one or more semiconductor devices 501 (e.g., transistors, diodes) formed in, on, or over the semiconductor substrate 502. In some examples, the semiconductor devices 501 may include, without limitation, bipolar junction transistors (BJTs), field-effect transistors (FETs), junction field-effect transistors (JFETs), metal-oxide-semiconductor field-effect transistors (MOSFETs), double-diffused metal-oxide-semiconductor (DMOS) transistors, laterally-diffused metal-oxide-semiconductor (LDMOS) transistors, complementary metal-oxide-semiconductor (CMOS) transistors (e.g., n-type MOS (NMOS) transistors, p-type MOS (PMOS) transistors), bipolar diodes (e.g., p-n junction diodes), unipolar diodes (e.g., metal-semiconductor junction (Schottky) diodes), bipolar-CMOS-DMOS (BCD) devices (e.g., integrated BJT, CMOS, and DMOS/LDMOS transistors on a single chip for mixed-signal (analog/digital) high-power applications), or combinations thereof.

In some examples, the semiconductor devices 501 may include n-type semiconductor devices (e.g., NMOS transistors), p-type semiconductor devices (e.g., PMOS transistors), or a combination thereof.

The device layer 504 also includes conductive contacts 503 on the semiconductor devices 501 (e.g., a source, drain, or gate contact 503 coupled to the source, drain, or gate of a transistor 501), which are electrically coupled to the internal interconnect layers 506 by vias 509.

The internal interconnect layers 506a-c include conductive features 505, such as traces or pads, embedded in dielectric material 511 (e.g., dielectric buildup material such as Ajinomoto Build-Up Film (ABF)). The conductive features 505 in different interconnect layers 506a-c are electrically coupled to each other by vias 509.

The external interconnect layer 508 includes conductive contacts 507 (e.g., pads) embedded in dielectric material 511 (e.g., solder resist) on the upper surface of IC device 500. The conductive contacts 511 are electrically coupled to the internal interconnect layers 506 by vias 509. Moreover, the conductive contacts 511 can be used to electrically couple IC device 500 to another external IC device (not shown), such as an IC die, IC package, or circuit board (e.g., PCB).

The conductive features 503, 505, 507 in different layers 504, 506a-c, 508 of IC device 500 are electrically coupled to each other by vias 509. Moreover, all of the conductive features 503, 505, 507, 509 in IC device 500 may be collectively referred to as conductive routing. The conductive routing 503, 505, 507, 509 may be used to route power or signals to, from, or between semiconductor devices 501 in the device layer 504 and any external IC devices electrically coupled to the surface contacts 507.

Although a certain number of internal interconnect layers 506a-c are shown in the illustrated example, IC device 500 may include any suitable number of interconnect layers 506. In some implementations, interconnect layers 506 that are higher up in the device stack (e.g., further from the device layer 504) may be thicker than interconnect layers 506 that are lower in the device stack. In some instances, interconnect layers 506a-c may be referred to as metal layers or metallization layers. As an example, interconnect layer 506a may be referred to as the metal 0 (M0) layer, interconnect layer 506b may be referred to as the metal 1 (M1) layer, and interconnect layer 506c may be referred to as the metal 2 (M2) layer.

The dielectric material 511 in the device layer 504, the internal interconnect layers 506, and the external interconnect layer 508 may vary across the respective layers. Moreover, the conductive features 503, 505, 507, 509 in IC device 500 may be formed of any suitable conductive materials (e.g., metal).

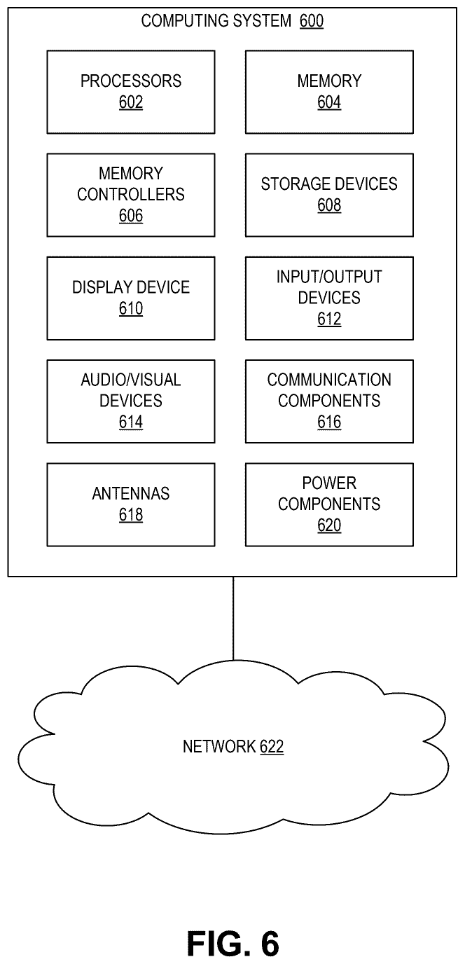

FIG. 6 illustrates an example computing system 600 that may include one or more JFETs in accordance with examples disclosed herein. In particular, certain components of computing system 600, such as the power components 620, may include one or more JFETs having any aspects of the example trench JFETs disclosed herein (e.g., JFET 100). For example, the power components 620 may include various components and circuitry used for power delivery and power management, which may be collectively referred to as power circuits or power circuitry. In some examples, one or more trench JFETs with separated source and gate regions (e.g., similar to JFET 100) may be included in at least some of the power circuits 620, such as protection circuits, solid-state circuit breakers, or power switching circuits, among other examples.

In the illustrated example, computing system 600 includes one or more processors 602, memory 604, memory controllers 606, storage devices 608, display devices 610, input/output (I/O) devices 612, audio/visual components 614, communication components 616, antennas 618, and power components 620. In some examples, the respective components of computing system 600 may be attached to or incorporated on a printed circuit board (PCB) (e.g., motherboard).

One or more of the processors 602 may include processing devices or processing units that include suitable hardware circuitry to enable the execution of instructions and the ability to perform calculations to carry out the operations of software, firmware, hardware, or any suitable combination thereof. One or more of the processors 602 may be embodied as single-core processing devices or multi-core processing devices. Circuitry of one or more processors 602 may be referred to herein as processing circuitry.

Any suitable operations disclosed herein may be performed by one or more of the processors 602. In some examples, processing circuitry of one or more processors 602 may be used to execute instructions that cause the processing circuitry to implement or perform functionality disclosed herein. The instructions may be stored on one or more non-transitory machine-readable storage media, such as memory 604 or storage devices 608.

Examples of possible types of processors 602 include, without limitation, a central processing unit (CPU), a microprocessor, an embedded processor, a digital signal processor (DSP), a system-on-a-chip (SoC), a co-processor, microcontroller, an accelerator, a graphics processing unit (GPU), an accelerated processing unit (APU), a visual processing unit (VPU), a deep learning processor (DLP), a neural network processing unit (NPU), a general purpose graphics processing unit (GPGPU), an inference accelerator, an application-specific integrated circuit (ASIC), a field-programmable gate array (FPGA), or any other processing device to execute code. One or more of the processors 602 may perform specialized processing tasks (e.g., graphics processing by GPUs, machine learning by DLPs, vision processing by VLPs, or the like). In some examples, one or more of the processors 602 may perform specialized processing tasks on behalf of one or more other processing devices such as CPUs or GPUs.

Memory 604 may include one or more memory devices for storing data (e.g., data that may be manipulated, generated, or otherwise used by processors 602 when performing operations). Memory 604 may include any form of volatile memory or non-volatile memory including, without limitation, random access memory (RAM), dynamic random access memory (DRAM), static random access memory (SRAM), ferroelectric random access memory (FeRAM), read-only memory (ROM), erasable programmable read-only memory (EPROM), electrically erasable read-only memory (EEPROM), flash memory, removable media, optical media, magnetic media (e.g., tape drives), any other suitable memory components, or any suitable combination thereof. Memory 604 may include one or more memory devices within the computing system 600, one or more memory devices separate from but communicatively coupled to the computing system 600, or any suitable combination thereof. Circuitry of memory 604 may be referred to herein as memory circuitry.

A memory hierarchy in computing system 600 may include one or more levels of cache (e.g., level one (L1), level two (L2), level three (L3), other levels of cache or combinations thereof). The cache levels may be within, close to, or accessible by the one or more processors 602. For example, one cache level may be close to or within a core of one processor 602 and accessible by that core. Another cache level may be close to a core of a processor 602 and shared with (and therefore, accessible by) another core of the same processor 602 or a different processor 602.

Memory devices of memory 604 may include one or more modules or layers of system memory coupled to the processors 602 through one or more memory controllers 606. Generally, the system memory may include some form of volatile memory (e.g., DRAM, RAM, SRAM). A portion or more of the system memory may be dedicated to a particular processing device. A portion or more of the system memory may be shared across one or more of the processors 602 in the computing system 600.

Memory controllers 606 may be used to manage access to memory 604, including reading and writing data on memory 604. Memory controllers 606 may be hardware interfaces that are integrated with, or external to, the processors 602. Memory controllers 606 may manage communication between processors 602 (e.g., CPU, GPU) and memory 604 (e.g., DRAM). In addition to memory controllers 606, computing system 600 may include other memory controller circuitry, including, without limitation, memory management units (MMUs), translation lookaside buffers (TLBs), load and store buffers, address generation units (AGUs), and address decoders. The memory controller circuitry may include electrical components, optical components, quantum components, semiconductor devices, logic elements, or any suitable combination thereof, to perform operations to read/load data from memory 604 and write/store data to memory 604. Data may be read/loaded from the closest memory 604 where it is stored (e.g., cache memory, system memory, storage devices, or remote memory). In addition, data may be written/stored to cache before being written/stored in system memory 604 or a storage device 608.

Storage devices 608 may include non-volatile memory or storage. In some instances, storage devices 608 may include any suitable characteristics described above with respect to memory 604. In some instances, storage devices 608 may have higher capacity and slower speed than memory 604. Thus, in some cases, storage devices 608 may be used for longer-term storage of data compared to memory 604. In some examples, storage device 608 includes one or more non-volatile storage devices, such as hard disk drives (HDDs), solid state drives (SSDs), removable storage devices (e.g., flash drives), other media (e.g., transitory machine readable storage media, non-transitory machine readable storage media), or any suitable combination thereof. Circuitry of one or more storage devices 602 may be referred to herein as storage circuitry.

Display device 610 may provide a visual interface that enables a user (e.g., human or robot) to interact with the computing system 600. The display device 610 may include any suitable screen or monitor that visually presents data in the form of text, images, video, graphical information, other data or information, or any combination thereof. The display device 610 may be integrated within the computing system 600 (e.g., as a laptop screen, tablet screen, smart phone screen, smart watch screen, or integrated screen of any other type of device) or may be an external device (e.g., desktop monitor, external monitor, television, projector) that is communicatively connected to the computing system 600. Data may be generated by the one or more processors 602 or received as input (e.g., from a user via an input device 612) and provided for display on the display device 610. In some scenarios, one or more additional display devices 610 may be integrated within, or communicatively connected to, the computing system 600. Circuitry of one or more display devices 610 may be referred to herein as display circuitry.

I/O devices 612 may provide interfaces for interacting or otherwise communicating with computing system 600. I/O devices 612 may include, without limitation, a keyboard, mouse, touchscreen (e.g., on display device 610), trackball, sensor, actuator, or global navigation satellite system (GNSS) receiver. Moreover, computing system 600 may include circuitry, such as an I/O controller, to enable I/O devices 612 to communicate with other components of computing system 600 (e.g., processors 602), which may be referred to herein as I/O circuitry.

Audio/visual components 614 may include devices used to provide audio or visual signals, including, without limitation, a camera, a microphone, or a speaker. Audio/visual devices 614 may be integrated or built into the computing system 600 or separate from and communicatively coupled to the computing system 600.

Communication components 616 may include hardware, software, firmware, or any suitable combination thereof to facilitate communications with other devices or systems external to computing system 600 (e.g., via a network 622). For example, communication components 616 may include one or more network interface controllers, network ports, antennas 618, network drivers and firmware, modems, routers, switches, adapters, or other suitable components. Circuitry of one or more communication components 616 may be referred to herein as communication circuitry.

The one or more antennas 618 may be used to facilitate wireless communication (e.g., over network 622). For example, an antenna 618 may be used to send or receive wireless signals (e.g., electromagnetic waves) using any suitable wireless communication technology, including, without limitation, any of the wireless technologies described below with respect to network 622.

The network 622 may include any type or topology of networks and may represent a series of points or nodes of interconnected communication pathways for receiving and sending network communications. Network 622 offers a communicative interface between nodes (e.g., computing system 600 and one or more remote devices also connected to the network) and may be configured as any local area network (LAN), virtual local area network (VLAN), wide area network (WAN), Internet, Intranet, Extranet, virtual private network (VPN), cloud network, any other appropriate architecture or system that facilitates communications in a network environment, or any suitable combination thereof. Network 622 may use any suitable technologies for communication, including, without limitation, wireless (e.g., 3G/4G/5G/nG network, Wireless Fidelity (Wi-Fi), worldwide interoperability for microwave access (WiMax), radio-frequency identification (RFID), near field communication (NFC), Bluetooth, amplitude modulation (AM) radio, frequency modulation (FM) radio, or the like), wired (e.g., Ethernet, fiber optic cables, powerlines, T1 lines), or any suitable combination thereof.

Power components 620 may manage the conversion, distribution, and regulation of electrical power for various subsystems of the computing system 600. Power components 620 may include, for example, one or more power supply units to convert AC power to DC power, voltage regulators to step down voltage from the power supply unit, power management integrated circuits (PMICs) to control power sequencing and delivery, or batteries (e.g., to provide the main source of power to computing system 600 or to provide an auxiliary power source, e.g., to retain BIOS or UEFI settings).

For ease of explanation, the concepts of this disclosure have been presented with reference to various illustrative examples, which have been described herein in detail and shown in the accompanying figures. However, the concepts of this disclosure are not limited to the particular examples disclosed, nor are the disclosed examples intended to be exhaustive. Rather, various modifications and alternative forms are also possible without departing from the spirit and scope of the concepts disclosed herein.

In the drawings, while some structural or method features may be shown in specific arrangements or orderings, such specific arrangements or orderings may be optional. In some examples, such features may be arranged in a different manner or order than shown in the drawings. Additionally, the inclusion of a structural or method feature in a particular drawing is not meant to imply that such feature is present in all examples and, in some examples, such feature may not be included or may be combined with other features. Further, the various examples shown in the drawings are illustrative representations and may not be drawn to scale. In some instances, the same or similar reference numerals may be used to designate the same or similar features in different drawings.

In the methods and process flows disclosed herein (e.g., the process flow of FIGS. 3A-G, the method of flowchart 400), additional operations may be performed beyond those that have been disclosed, certain operations may be omitted, or the order in which certain operations are performed may vary.

The disclosed examples may be implemented, in some cases, in hardware, firmware, software, or any combination thereof. The disclosed examples may also be implemented as instructions carried by or stored on one or more transitory or non-transitory machine-readable (e.g., computer-readable) storage media, which may be read and executed by processing circuitry (e.g., on one or more processors). A machine-readable storage medium may be embodied as any storage device, mechanism, or other physical structure for storing or transmitting information in a form readable by a machine, including volatile or non-volatile memory (e.g., random access memory (RAM), flash memory), hard drives (e.g., hard disk drive (HDD), solid state drive (SSD)), media discs, or combinations thereof.

As used herein, the term “logic” may refer to hardware (e.g., circuitry), firmware, software, or any combination thereof configured to perform one or more functions. Logic may be implemented using digital circuits such as combinational logic gates, sequential circuits, programmable logic devices, application-specific integrated circuits (ASICs), field-programmable gate arrays (FPGAs), microprocessors, or microcontrollers. In some embodiments, logic may also include software or firmware instructions stored in memory and executed by one or more processing units.

As used herein, the term “or” is intended to be inclusive rather than exclusive. That is, unless otherwise indicated or as would be apparent to one of skill in the art, the use of “or” means any combination of the referenced elements. For example, the phrase “A or B” can mean “A, B, or both A and B.” The singular terms “a,” “an,” and “the” are intended to encompass their plural counterparts as well, unless it is clear from the context that a different interpretation is intended. A list of items referenced by phrases such as “at least one of” or “one or more of” is intended to include any combination of the listed items. For example, the phrase “at least one of A, B, or C” or “one or more of A, B, or C” can mean A; B; C; A and B; A and C; B and C; or A, B, and C.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

As used herein, references to an “example” or “examples” may refer to one or more of the same or different examples. Some examples may have some, all, or none of the features described for other examples.

### EXAMPLES

The following examples pertain to the subject matter disclosed herein. In accordance with this disclosure, a system, device, apparatus, method, machine-readable storage medium, or combination thereof, can include features from one or a combination of the following examples.

Example 1 includes a semiconductor device, comprising: a source region within a mesa, wherein the source region has a first conductivity type; a drain region below the source region, wherein the drain region has the first conductivity type; a drift region extending vertically between the source region and the drain region, wherein the drift region has the first conductivity type, and wherein the drift region has a lower doping concentration than the source region and the drain region; and a plurality of gate regions below trenches on opposite sides of the mesa, wherein the gate regions are separated from the source region, and wherein the gate regions have a second conductivity type different than the first conductivity type.

Example 2 includes the semiconductor device of Example 1, wherein the gate regions extend vertically below the trenches and laterally towards each other.

Example 3 includes the semiconductor device of any of Examples 1-2, wherein the gate regions do not extend to the source region.

Example 4 includes the semiconductor device of any of Examples 1-3, wherein the gate regions are not in direct contact with the source region.

Example 5 includes the semiconductor device of any of Examples 1-4, wherein the gate regions are outside of the mesa.

Example 6 includes the semiconductor device of any of Examples 1-5, wherein the gate regions are not within the mesa.

Example 7 includes the semiconductor device of any of Examples 1-6, wherein the source region and the gate regions are separated by the drift region.

Example 8 includes the semiconductor device of any of Examples 1-7, wherein the plurality of gate regions respectively comprise a first gate region and a second gate region, wherein the second gate region is below the first gate region, wherein the second gate region is wider than the first gate region, and wherein the second gate region extends further laterally into the drift region than the first gate region.

Example 9 includes the semiconductor device of any of Examples 1-8, further comprising a channel region, wherein the channel region is within the drift region and between the gate regions.

Example 10 includes the semiconductor device of Example 9, wherein the drift region is narrower in the channel region and wider above and below the channel region.

Example 11 includes the semiconductor device of any of Examples 1-10, wherein: the first conductivity type is n-type conductivity and the second conductivity type is p-type conductivity; or the first conductivity type is p-type conductivity and the second conductivity type is n-type conductivity.

Example 12 includes the semiconductor device of any of Examples 1-11, wherein: the source region, the drain region, and the drift region respectively comprise a doped semiconductor material having the first conductivity type; and the gate regions respectively comprise a doped semiconductor material having the second conductivity type.

Example 13 includes the semiconductor device of any of Examples 1-12, wherein the source region, the drain region, the drift region, and the gate regions respectively comprise: silicon and carbon; or silicon.

Example 14 includes the semiconductor device of any of Examples 1-13, wherein: the source region, the drain region, and the drift region are doped with an n-type dopant and the gate regions are doped with a p-type dopant; or the source region, the drain region, and the drift region are doped with the p-type dopant and the gate regions are doped with the n-type dopant.

Example 15 includes the semiconductor device of Example 14, wherein: the n-type dopant comprises phosphorus or arsenic; and the p-type dopant comprises boron or aluminum.

Example 16 includes the semiconductor device of any of Examples 1-15, wherein the drain region is comprised in a substrate.

Example 17 includes the semiconductor device of any of Examples 1-16, further comprising: a source contact coupled to the source region; a drain contact coupled to the drain region; and a plurality of gate contacts coupled to the gate regions.

Example 18 includes the semiconductor device of any of Examples 1-17, further comprising a junction field-effect transistor (JFET), wherein the JFET comprises the source region, the drain region, the gate regions, and the drift region.

Example 19 includes the semiconductor device of Example 18, wherein the JFET is an n-type JFET, wherein the first conductivity type is n-type conductivity, and wherein the second conductivity type is p-type conductivity.

Example 20 includes the semiconductor device of Example 18, wherein the JFET is a p-type JFET, wherein the first conductivity type is p-type conductivity, and wherein the second conductivity type is n-type conductivity.

Example 21 includes the semiconductor device of any of Examples 18-20, wherein the JFET is a vertical trench JFET.

Example 22 includes the semiconductor device of any of Examples 1-21, wherein: when no voltage is applied to the gate regions, current flows from the source region to the drain region; and when a threshold voltage is applied to the gate regions, current does not flow from the source region to the drain region.

Example 23 includes a semiconductor device, comprising: a first region within a mesa, wherein the first region comprises a doped semiconductor material having a first conductivity type; a second region below the first region, wherein the second region comprises a doped semiconductor material having the first conductivity type; a third region extending vertically between the first region and the second region, wherein the third region comprises a doped semiconductor material having the first conductivity type, and wherein the third region has a lower doping concentration than the first region and the second region; and a plurality of fourth regions on opposite sides of the third region, wherein the fourth regions do not extend to the first region, and wherein the fourth regions comprise a doped semiconductor material having a second conductivity type different than the first conductivity type.

Example 24 includes the semiconductor device of Example 23, wherein: the first region is a source region; the second region is a drain region; the third region is a drift region; and the plurality of fourth regions are a plurality of gate regions.

Example 25 includes a power circuit, comprising: one or more junction field-effect transistors (JFETs), wherein the one or more JFETs respectively comprise a source region, a drain region, a drift region, and a plurality of gate regions, wherein: the source region is within a mesa; the drain region is below the source region; the drift region is between the source region and the drain region; and the gate regions are below trenches on opposite sides of the mesa, wherein the gate regions do not extend to the source region.

Example 26 includes the power circuit of Example 25, wherein the gate regions extend vertically away from the source region and laterally towards each other.

Example 27 includes the power circuit of any of Examples 25-26, wherein: the source region, the drain region, and the drift region respectively comprise a doped semiconductor material having a first conductivity type; and the gate regions respectively comprise a doped semiconductor material having a second conductivity type, wherein the second conductivity type is different than the first conductivity type.

Example 28 includes the power circuit of any of Examples 25-27, wherein the power circuit is a protection circuit.

Example 29 includes the power circuit of any of Examples 25-27, wherein the power circuit is a solid-state circuit breaker.

Example 30 includes the power circuit of any of Examples 25-27, wherein the power circuit is a power switching circuit.

Example 31 includes a method, comprising: receiving a substrate, wherein the substrate comprises a first doped semiconductor material having a first conductivity type; forming a drift layer over the substrate, wherein the drift layer comprises a second doped semiconductor material having the first conductivity type; implanting a first type of dopant ions in a source region of the drift layer, wherein the first type of dopant ions correspond to the first conductivity type; implanting a second type of dopant ions in a plurality of lower gate regions of the drift layer, wherein the second type of dopant ions correspond to a second conductivity type different than the first conductivity type; implanting the second type of dopant ions in a plurality of upper gate regions of the drift layer; and forming a plurality of trenches in the upper gate regions.

Example 32 includes the method of Example 31, wherein the lower gate regions are below the upper gate regions, and wherein the lower gate regions are wider than the upper gate regions.

Example 33 includes the method of any of Examples 31-32, wherein: the first conductivity type is n-type conductivity and the second conductivity type is p-type conductivity; or the first conductivity type is p-type conductivity and the second conductivity type is n-type conductivity.

Example 34 includes the method of any of Examples 31-33, wherein the first doped semiconductor material and the second doped semiconductor material respectively comprise: silicon and carbon; or silicon.

Example 35 includes the method of any of Examples 31-34, further comprising forming a plurality of conductive contacts, wherein the conductive contacts are respectively formed on the source region, a drain region, and the upper gate regions, wherein the drain region is comprised in the substrate.

Example 36 includes an integrated circuit comprising the semiconductor device of any of Examples 1-24.

Example 37 includes an electronic device comprising the semiconductor device of any of Examples 1-24.

Example 38 includes a system comprising the semiconductor device of any of Examples 1-24.

Example 39 includes the system of Example 38, further comprising power circuitry, wherein the semiconductor device is comprised in the power circuitry.

Example 40 includes the system of Example 39, wherein the power circuitry comprises protection circuitry, solid-state circuit breaker circuitry, or power switching circuitry, wherein the semiconductor device is comprised in the protection circuitry, the solid-state circuit breaker circuitry, or the power switching circuitry.

Example 41 includes the system of any of Examples 38-40, further comprising one or more of: a printed circuit board (PCB); a processor; a memory; a data storage device; a network interface controller; or an input/output (I/O) controller.

Example 42 includes the system of Example 41, wherein the processor comprises a central processing unit (CPU) or a graphics processing unit (GPU).

Example 43 includes a method of forming the semiconductor device of any of Examples 1-24.

Example 44 includes one or more non-transitory machine-readable storage media having instructions stored thereon, wherein the instructions, when executed by processing circuitry, cause the processing circuitry to perform the method of any of Examples 31-35 or 43.

1. A semiconductor device, comprising:
a source region within a mesa, wherein the source region has a first conductivity type;
a drain region below the source region, wherein the drain region has the first conductivity type;
a drift region extending vertically between the source region and the drain region, wherein the drift region has the first conductivity type, and wherein the drift region has a lower doping concentration than the source region and the drain region; and
a plurality of gate regions below trenches on opposite sides of the mesa, wherein the gate regions are separated from the source region, and wherein the gate regions have a second conductivity type different than the first conductivity type.

2. The semiconductor device of claim 1, wherein the gate regions extend vertically below the trenches and laterally towards each other.

3. The semiconductor device of claim 1, wherein the gate regions do not extend to the source region.

4. The semiconductor device of claim 1, wherein the plurality of gate regions respectively comprise a first gate region and a second gate region, wherein the second gate region is below the first gate region, wherein the second gate region is wider than the first gate region, and wherein the second gate region extends further laterally into the drift region than the first gate region.

5. The semiconductor device of claim 1, further comprising a channel region, wherein the channel region is within the drift region and between the gate regions.

6. The semiconductor device of claim 5, wherein the drift region is narrower in the channel region and wider above and below the channel region.

7. The semiconductor device of claim 1, wherein:
the first conductivity type is n-type conductivity and the second conductivity type is p-type conductivity; or
the first conductivity type is p-type conductivity and the second conductivity type is n-type conductivity.

8. The semiconductor device of claim 1, wherein:
the source region, the drain region, and the drift region respectively comprise a doped semiconductor material having the first conductivity type; and
the gate regions respectively comprise a doped semiconductor material having the second conductivity type.

9. The semiconductor device of claim 1, wherein the source region, the drain region, the drift region, and the gate regions respectively comprise:
silicon and carbon; or
silicon.

10. The semiconductor device of claim 1, further comprising:
a source contact coupled to the source region;
a drain contact coupled to the drain region; and
a plurality of gate contacts coupled to the gate regions.

11. The semiconductor device of claim 1, further comprising a junction field-effect transistor (JFET), wherein the JFET comprises the source region, the drain region, the gate regions, and the drift region.

12. The semiconductor device of claim 1, wherein:
when no voltage is applied to the gate regions, current flows from the source region to the drain region; and
when a threshold voltage is applied to the gate regions, current does not flow from the source region to the drain region.

13. A power circuit, comprising:
one or more junction field-effect transistors (JFETs), wherein the one or more JFETs respectively comprise a source region, a drain region, a drift region, and a plurality of gate regions, wherein:
the source region is within a mesa;
the drain region is below the source region;
the drift region is between the source region and the drain region; and
the gate regions are below trenches on opposite sides of the mesa, wherein the gate regions do not extend to the source region.

14. The power circuit of claim 13, wherein the gate regions extend vertically away from the source region and laterally towards each other.

15. The power circuit of claim 13, wherein the power circuit is a protection circuit.

16. The power circuit of claim 13, wherein the power circuit is a solid-state circuit breaker.

17. The power circuit of claim 13, wherein the power circuit is a power switching circuit.

18. A method, comprising:
receiving a substrate, wherein the substrate comprises a first doped semiconductor material having a first conductivity type;
forming a drift layer over the substrate, wherein the drift layer comprises a second doped semiconductor material having the first conductivity type;
implanting a first type of dopant ions in a source region of the drift layer, wherein the first type of dopant ions correspond to the first conductivity type;
implanting a second type of dopant ions in a plurality of lower gate regions of the drift layer, wherein the second type of dopant ions correspond to a second conductivity type different than the first conductivity type;
implanting the second type of dopant ions in a plurality of upper gate regions of the drift layer; and
forming a plurality of trenches in the upper gate regions.

19. The method of claim 18, wherein the lower gate regions are below the upper gate regions, and wherein the lower gate regions are wider than the upper gate regions.

20. The method of claim 18, further comprising forming a plurality of conductive contacts, wherein the conductive contacts are respectively formed on the source region, a drain region, and the upper gate regions, wherein the drain region is comprised in the substrate.
